(19) United States
(12) Patent Application Publication
(10) Pub. No.: US 2012/0218712 A1
(43) Pub. Date: Aug. 30, 2012

(54) SPRING FIXTURE FOR ELECTRONIC COMPONENT AND HEAT SINK STRUCTURE

(75) Inventor: Kiyoshi HAYASHI, Tokyo (JP)

(73) Assignee: TDK CORPORATION, Tokyo (JP)

(21) Appl. No.: 13/405,617

(22) Filed: Feb. 27, 2012

(30) Foreign Application Priority Data
Feb. 28, 2011 (JP) 2011-042789

(51) Int. Cl. H05K 7/20; F16D 1/00

(52) U.S. Cl. 361/704; 403/327

(57) ABSTRACT

A spring fixture includes a base, first and second holding parts extending in opposite lateral directions from the base, and a height registration part extending downwardly from the base relative to the lateral directions. The heat sink member has a height adjustment hole at a location corresponding to the height registration part. The height registration part is inserted through the height adjustment hole so that electronic components are fixed to a heat sink member by the first and second holding parts. A distance between the base and the heat sink member can be changed by varying a size of the height adjustment hole to accommodate varying heights of the electronic components. Therefore, the spring fixture can be used for various types of the electronic components with different heights without changing the designs and manufacturing methods for the spring fixture.

### CROSS-REFERENCE TO RELATED APPLICATION

This application claims priority to Japanese Patent Application No. 2011-42789 filed Feb. 28, 2011 which is hereby expressly incorporated by reference herein in its entirety.

### BACKGROUND

The present application relates to a fixture that fixes an electronic component having a large amount of heat generation to a heat sink member. The electronic component can be a semiconductor device, such as a transistor and a diode, which is mounted in electronic equipment.

Japanese Utility Model Publication Numbers JPU H05-46086 and JPU S63-137995 disclose fixtures that fix an electronic component, such as a semiconductor device that is mounted in electronic equipment, to a heat sink member. The fixtures fix two electronic components on both flanks of the heat sink member so that a fixing part is at the center.

JPU H05-46086 discloses a method for fixing the electronic components to a heat sink plate of the heat sink member by using a holder. The holder is configured with a base having a mounting hole and a pair of approximately L-shaped holding plates that extend up from two opposite sides of the base and then extend laterally. The laterally extending parts of the holding plates slope downwardly to their tips from the vertically extending parts of the holding plates. A revolving prevention plate extends from a front side of the base. A tip part of the revolving prevention plate is bent in a lower direction so as to form a bent part. When the electronic components are fixed to the heat sink plate by the holder, the electronic components are covered by the holder from above. When the bent part of the revolving prevention plate engages with an edge of the heat sink plate, the mounting hole of the base is aligned with a mounting hole of one of the electronic components. A screw is inserted in the mounting holes from below to secure them together. As discussed above, when the holder is attached to the heat sink plate, the holder does not come off because the bent part of the revolving prevention plate engages with the edge of the heat sink plate. Because surfaces of the electronic components are pressed down by the holding plates, the holding plates, which slope downward, are now in a lateral state. Thus, the electronic components are tightly fixed to the heat sink plate by a downward spring back force. As a result, a uniform force is applied to the entirety of the electronic components.

In JPU S63-137995, after transistors are mounted on a heat sink plate with an insulating sheet therebetween, a pressing member is assembled over the transistors with a spacer therebetween. A stud-shaped screw that is attached to the heat sink plate is fitted with internal threads of the pressing member so as to tightly fix the transistors to the heat sink plate with the insulating sheet therebetween. The spacer has planar and curved surfaces. The planar surfaces are formed at places that contact the transistors. The curved surfaces are formed at places that contact the pressing member above the transistors. When the pressing member presses the spacer by tightening the screw, a nearly uniform pressing force is applied to each of the transistors from above. Therefore, the transistors are tightly fixed to the heat sink plate with the insulating sheet therebetween without unevenly pressing the transistors toward the insulating sheet on the heat sink plate.

However, JPU H05-46086 and JPU S63-137995 have the following problems. In JPU H05-46086, because a gap between the base that is fixed to the heat sink plate and the holding plates that press the electronic components in the case of using the holder is different in accordance with a thickness of the electronic components, it is necessary to adjust the gap, i.e., the height between the heat sink plate and the holding plates. The adjustment is performed in accordance with the different thicknesses of the electronic components in the case in which different electronic components are used for each production process and in accordance with the different thicknesses of the electronic components by manufacturing tolerances. In JPU S63-137995, because the heat sink plate does not contact the pressing member and the spacer, an excessive pressing force is applied to the electronic components at the time of tightening by the screw. As a result, the electronic components might be broken. Further, when the heights of two electronic components are different from each other, the pressing member and the spacer are fixed and sloped relative to the heat sink plate. As a result, the pressing member and the spacer, and/or the electronic components might be deformed.

### SUMMARY

In the present application, when electronic components are fixed to a heat sink member by a spring fixture, a height of the spring fixture is adjusted to account for the different heights of the electronic components by embedding a part of the spring fixture into a hole provided in the heat sink member. Thus, the electronic components are easily attached to the heat sink member without regard to the height differences among the electronic components. An object of the present application is to provide such a spring fixture for a semiconductor device.

A spring fixture according to the present application comprises a base having first through fourth sides, a first holding part extending from the first side of the base in a first lateral direction for pressing a first electronic component toward a heat sink member, a second holding part extending from the second side of the base opposite to the first side, the second holding part extending in a second lateral direction opposite to the first lateral direction for pressing a second electronic component toward the heat sink member, and a first height registration part extending from the third side of the base in a downward direction relative to the first and second lateral directions and having a tapered shape. The first and second electronic components are fixed to the heat sink member by the first and second holding parts.

According to another aspect of the present application, the spring fixture further includes a threaded hole provided in the base, and a screw securing the base and the heat sink member. The screw is inserted from the heat sink member to the base through the threaded hole to tighten the heat sink member to the base.

According to another aspect of the present application for the spring fixture, the first height registration part is configured with a first body part at a proximal end close to the base, and a first tip part at a distal end far from the base, and the first body part has a sloped shape so that a first width of the first tip part is narrower than a second width of the first body part.

According to another aspect of the present application, the spring fixture further includes a first fixing part provided at a first end of the first holding part, the first fixing part having a first planar surface, and a second fixing part provided at a second end of the second holding part, the second fixing part having a second planar surface. Thus, the first and second planar surfaces contact the first and second electronic components, respectively, so as to fix the first and second electronic components to the heat sink member by surface contact.

According to another aspect of the present application, the spring fixture further includes a second height registration part extending from the fourth side of the base opposite to the third side, the second height registration part extending in the downward direction and having a tapered shape, a first height adjustment hole provided in the heat sink member at a first location corresponding to the first height registration part, and a second height adjustment hole provided in the heat sink member at a second location corresponding to the second height registration part. The first and second height registration parts are inserted through the first and second height adjustment holes, respectively, so that the first and second electronic components are fixed to the heat sink member by the first and second holding parts.

According to another aspect of the present application for the spring fixture, the second height registration part includes a second body part at a proximal end close to the base, and a second tip part at a distal end far from the base, and the second body part has a sloped shape so that a third width of the second tip part is narrower than a fourth width of the second body part.

A heat sink structure according to the present application comprises first and second electronic components, a heat sink member, and a spring fixture. The spring fixture includes a base having first through fourth sides, a first holding part extending from the first side of the base in a first lateral direction and pressing the first electronic component toward the heat sink member, a second holding part extending from the second side of the base opposite to the first side, the second holding part extending in a second lateral direction opposite to the first lateral direction and pressing the second electronic component toward the heat sink member, and a first height registration part extending from the third side of the base in a downward direction relative to the first and second lateral directions and having a tapered shape. A first height adjustment hole is provided in the heat sink member at a first location corresponding to the first height registration part. The first height registration part is inserted through the first height adjustment hole so that the first and second electronic components are fixed to the heat sink member by the first and second holding parts.

According to another aspect of the present application for the heat sink structure, a first distance between the base and the heat sink member is changed by varying a size of the first height adjustment hole.

According to another aspect of the present application, the heat sink structure further includes a threaded hole provided in the base, a through hole provided in the heat sink member, and a screw securing the base and the heat sink member. The screw is inserted from the heat sink member to the base through the through hole and the threaded hole to tighten the heat sink member to the base.

According to another aspect of the present application for the heat sink structure, the first height registration part includes a first body part at a proximal end close to the base, and a first tip part at a distal end far from the base, and the first body part has a sloped shape so that a first width of the first tip part is narrower than a second width of the first body part.

According to another aspect of the present application, the heat sink structure further includes a first fixing part provided at a first end of the first holding part, the first fixing part having a first planar surface, and a second fixing part provided at a second end of the second holding part, the second fixing part having a second planar surface. Thus, the first and second planar surfaces contact the first and second electronic components, respectively, so as to fix the first and second electronic components to the heat sink member by surface contact.

According to another aspect of the present application, the heat sink structure further includes a second height registration part extending from the fourth side of the base opposite to the third side, the second height registration part extending in the downward direction and having a tapered shape, and a second height adjustment hole provided in the heat sink member at a second location corresponding to the second height registration part. The second height registration part is inserted through the second height adjustment hole so that the first and second electronic components are fixed to the heat sink member by the first and second holding parts.

According to another aspect of the present application for the heat sink structure, the second height registration part includes a second body part at a proximal end close to the base, and a second tip part at a distal end far from the base, and the second body part has a sloped shape so that a third width of the second tip part is narrower than a fourth width of the second body part.

According to another aspect of the present application for the heat sink structure, a first distance between the base and the heat sink member is changed by varying sizes of the first and second height adjustment holes.

According to the present application, a spring fixture can be used for electronic components having different heights by changing a size of a height adjustment hole provided in a heat sink member. As a result, several electronic components having different heights can be fixed to the heat sink member. Therefore, it is not necessary to change the designs and manufacturing methods for the spring fixture. Because one type of spring fixture with the same design and size can be used for several electronic components, it is not necessary to manufacture several variations of spring fixtures. Thus, it is possible to prevent the number of parts in inventory from increasing. The costs related to the spring fixture can also be decreased.

Further, since a height registration part provided at the spring fixture is embedded and fitted in the height adjustment hole provided in the heat sink member, the electronic components can be fixed and sandwiched by the spring fixture and the heat sink member. Thus, the positioning of the electronic components can be easily performed.

Because the height registration part comes into contact with the heat sink member, an excessive pressing force is not applied to the electronic components. Thus, breaking and cracking of the electronic components can be prevented.

An assembly process after the positioning of the electronic components only involves the tightening of a screw. Thus, the assembly processes and process of operation can be simplified and efficiency can be increased.

Because the structure of the spring fixture is simple, it is not necessary to make the spring fixture with complex manufacturing processes. Thus, the manufacturing processes can also be simplified so that excellent mass productivity can be realized.

### BRIEF DESCRIPTION OF THE DRAWINGS

Embodiments according to the present application will be described with reference to the accompanying drawings, wherein like numbers reference like elements.

FIG. 1 is an exploded perspective view of a heat sink structure according to a first embodiment of the present invention.

FIG. 2 is a perspective view of a heat sink structure according to a first embodiment of the present invention.

FIG. 3 is a perspective view of a fitting state between a height registration part and a height adjustment hole as seen from the back side of a heat sink structure according to a first embodiment of the present invention.

FIG. 4A is a perspective view of a spring fixture according to a first embodiment of the present invention.

FIG. 4B is a perspective view of a spring fixture according to a first embodiment of the present invention as seen from the back side.

FIG. 5A is a side view of a heat sink structure according to a first embodiment of the present invention.

FIG. 5B is a partial enlarged sectional view of a height adjustment hole and a height registration part of a heat sink structure shown in FIG. 5A.

FIG. 6A is a side view of a heat sink structure when a size of a height adjustment hole is larger than that of FIG. 5A according to a first embodiment of the present invention.

FIG. 6B is a partial enlarged sectional view of a height adjustment hole and a height registration part of a heat sink structure shown in FIG. 6A.

### DESCRIPTION OF EXEMPLARY EMBODIMENTS

### 1. Configuration of Heat Sink Structure

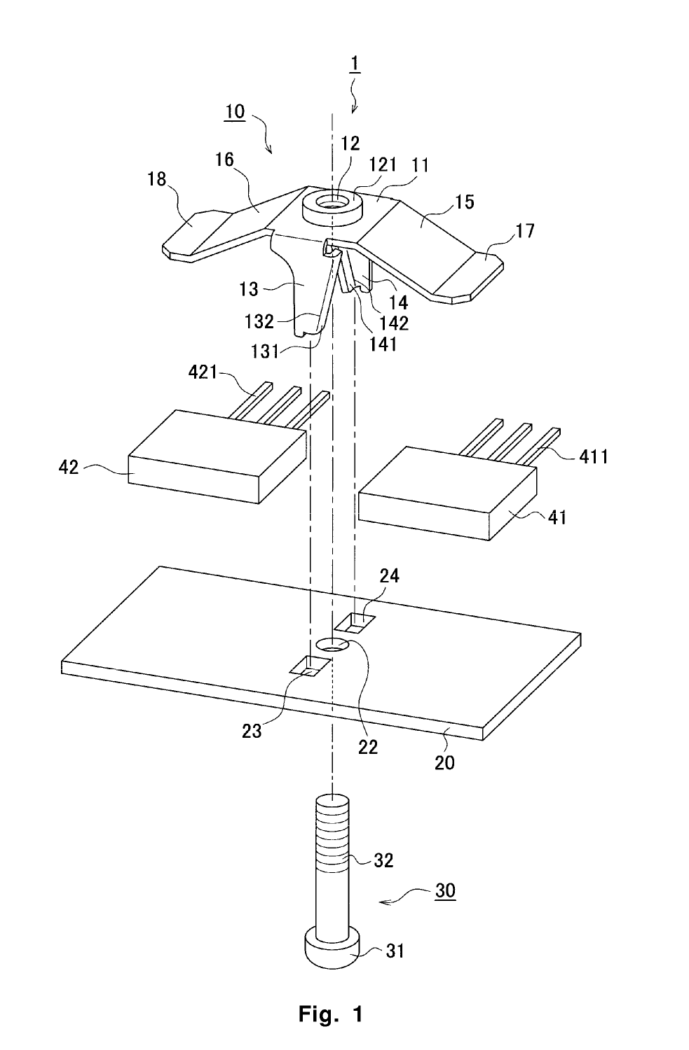

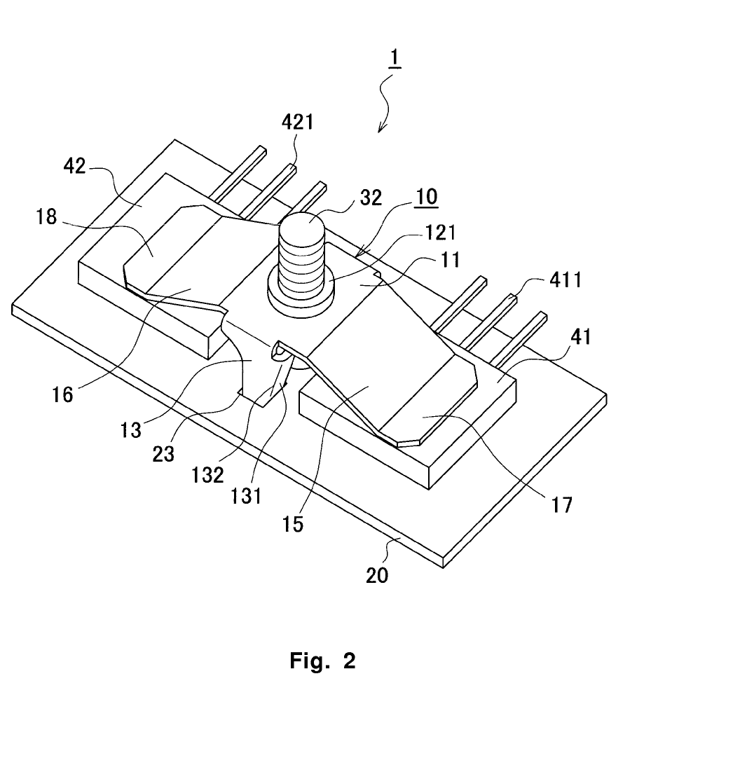

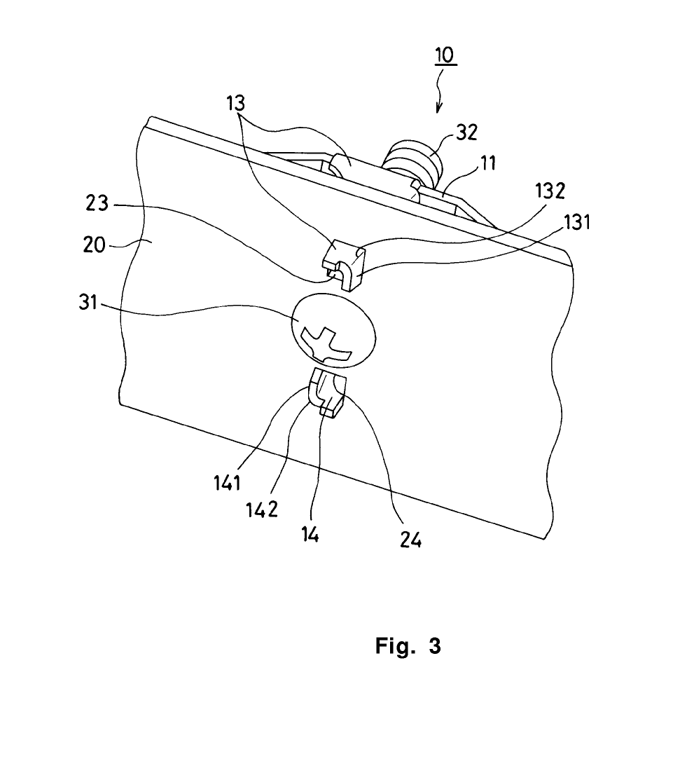

A first embodiment of a heat sink structure 1 according to the preset invention will be explained below with reference to FIGS. 1 through 3. FIG. 1 is an exploded perspective view of the heat sink structure 1 according to the first embodiment. FIG. 2 is a perspective view of the heat sink structure 1 according to the first embodiment. FIG. 3 is a perspective view of a fitting state between a height registration part 13(14) and a height adjustment hole 23(24) as seen from the back side of the heat sink structure 1 according to the first embodiment.

The heat sink structure 1 as shown in FIGS. 1 through 3 is for efficiently radiating heat of an electronic component and for realizing fixed contact between a heat sink member and the electronic component that is used at a circuit board of electronic equipment such as a power supply device. The heat sink structure 1 shown in FIG. 1 is configured with a spring fixture 10, a heat sink member 20, electronic components 41, 42 that are placed on the heat sink member 20, and a screw 30 that tightens between the heat sink member 20 and the spring fixture 10.

The heat sink member 20 has a plane on which the electronic components 41, 42 are tightly fixed in order to ensure the fixed contact between the electronic components 41, 42 and the heat sink member 20. The heat sink member 20 also functions to radiate heat that is generated at the electronic components 41, 42 that are placed on the heat sink member 20. It is preferred that a material of the heat sink member 20 is a high heat conducting metal such as aluminum or copper for radiating heat. A through screw hole 22 through which a threaded part 32 of the screw 30 passes and height adjustment holes 23, 24 in which height registration parts 13, 14 of the spring fixture 10 are fitted are provided in the heat sink member 20. The height adjustment holes 23, 24 are symmetrical with respect to the through screw hole 22 and are provided in proximity to the through screw hole 22. Furthermore, the sizes and shapes of the height adjustment holes 23, 24 are selected to correspond to a cross sectional shape of the height registration parts 13, 14 because the height registration parts 13, 14 are inserted in the height adjustment holes 23, 24.

The screw 30 is configured with a screw head 31 and the threaded part 32. The diameter of the screw head 31 is designed to be larger than the hole diameter of the through screw hole 22. This design prevents the screw 30 from backing out from the through screw hole 22. Thread ridges are formed at the threaded part 32. The threaded part 32 mates with a threaded hole 12 and a screw hole rising part 121 of the spring fixture 10.

The electronic components 41, 42 are, for example, a transistor and/or a diode. The electronic components 41, 42 have terminals 411, 421, respectively. Electrical connection is obtained by connecting the terminals 411, 421 to a circuit board through soldering. The electronic components 41, 42 generate a large amount of heat during operations due to applied voltage. The generated heat causes a performance loss of the electronic components 41, 42. In order to recover from the performance loss, it is necessary to lower the temperature of the electronic components 41, 42 by radiating the heat. It is preferred that the efficiency of heat conduction is improved by increasing a contact area between the electronic components 41, 42 and the heat sink member 20 and by tightly fixing the electronic components 41, 42 and the heat sink member 20 together to radiate the heat in a short period of time with efficiency. Thus, it is desirable for the bottom surfaces of the electronic components 41, 42 to be tightly fixed to the heat sink member 20 with surface contact.

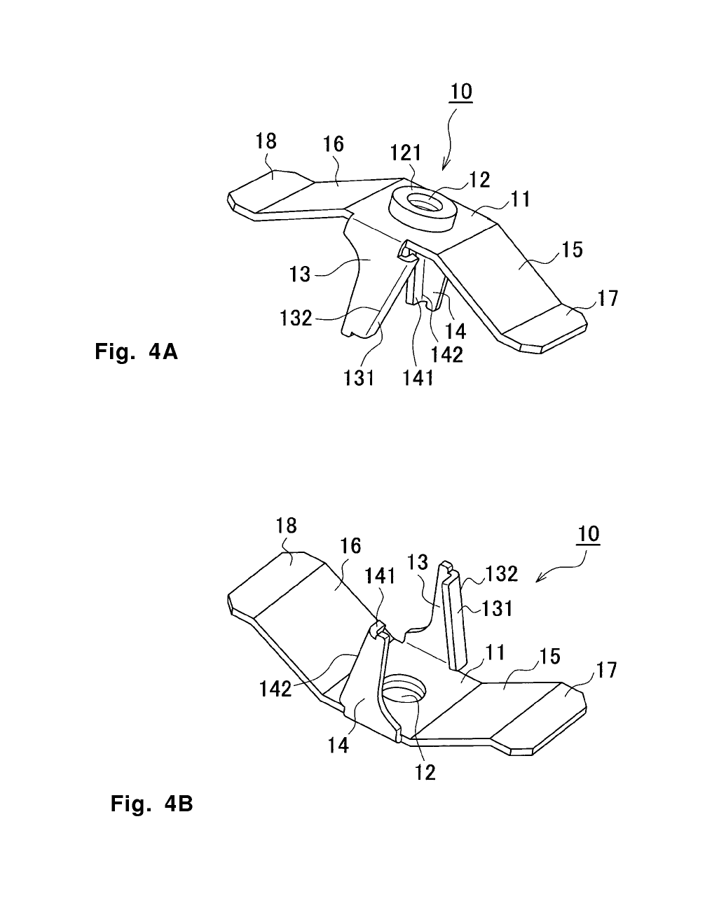

Next, a configuration of the spring fixture 10 is explained below with reference to FIGS. 4A and 4B. FIG. 4A is a perspective view of the spring fixture 10 according to the first embodiment of the present invention. FIG. 4B is a perspective view of the spring fixture 10 according to the first embodiment of the present invention as seen from the back side.

The spring fixture 10 includes a base 11 having a rectangular shape that extends in a horizontal (lateral) direction and the height registration parts 13, 14 that are configured to extend vertically downward (toward the heat sink member 20) from two opposite sides of the base 11 as shown in FIG. 4A. Although one of the height registration parts 13, 14 is sufficient to adjust (position) a distance between the spring fixture 10 and the heat sink member 20, in the present embodiment, two of the height registration parts 13, 14 are exemplarily shown. Further, the base 11 includes the holding parts 15, 16 that extend from other two opposite sides of the base 11 in horizontal (lateral) directions. Specifically, the holding parts 15, 16 extend obliquely downward relative to the horizontal directions. Fixing parts 17, 18 are provided at the ends of the holding parts 15, 16, respectively.

The material for the spring fixture 10 is not necessarily limited so long as it is a metal plate or a resin plate that can be processed into the shape of a spring fixture.

The threaded hole 12 is provided at the center of the base 11. The screw hole rising part 121, which rises vertically upward from the threaded hole 12, is provided at the circumference of the threaded hole 12. Thread ridges (not shown) are formed at the internal surfaces of the threaded hole 12 and the screw hole rising part 121 so that the threaded ridges mate with the threaded part 32 of the screw 30. The screw hole rising part 121 is provided in order to secure the tightened mating between the screw hole rising part 121 and the threaded part 32 of the screw 30 by increasing an area of the mating surface.

The height registration parts 13, 14 have tapered shapes toward the tips of the height registration parts 13, 14. Namely, at least one of two sides at the body parts of the height registration parts 13, 14 that extend toward the heat sink member 20 are sloped shape parts 132, 142 that are angled relative to a vertical direction from the base 11 to tip parts of the height registration parts 13, 14. A width of the body parts close to the base 11 is wider than that of the tip parts so that the width gradually narrows from the base 11 to the tips of the height registration parts 13, 14. Bent parts 131, 141 is provided at the same sides as the sloped shape parts 132, 142, which are in slope shapes, of the height registration parts 13, 14 from the base 11 to the tip parts. But, the bent parts 131, 141 can be provided at other sides, which are not in slope shapes, of the height registration parts 131, 141. The bent parts 131, 141 are perpendicular to the height registration parts 13, 14 and extend laterally from the height registration parts 13, 14 toward a bottom surface of the base 11. The height registration parts 13, 14 and the bent parts 131, 141 are symmetrical with respect to the center of the base 11. This allows a force to be distributed equally when they are inserted in the corresponding height adjustment holes 23, 24. A cross-sectional surface of the height registration part 13 and the bent part 131, and a cross-sectional surface of the height registration part 14 and the bent part 141 are in L-shapes that function as a rib to reinforce the strength of the height registration parts 13, 14. The sloped shape parts 132, 142 of the height registration parts 13, 14 do not have to be provided at only one side, but can also be provided at both sides of each of the height registration parts 13, 14. Further, the bent parts 131, 141 do not have to be provided at only one side, but can also be provided at both sides of each of the height registration parts 13, 14.

Furthermore, although the height registration parts 13, 14 have the tapered shape in which a width of the tip part is narrower than that of the body part, other shapes for the height registration parts 13, 14 can be conical shape, triangular pyramid, and quadrangular pyramid. When the required strength for the height registration parts 13, 14 is secured, it is not necessary to provide the bent parts 131, 141. So long as the height registration parts 13, 14 and the bent parts 131, 141 can be fitted in the corresponding height adjustment holes 23, 24, and so long as the sloped shape parts 132, 142 are configured to come into contact with the height adjustment holes 23, 24, other shapes for the height registration parts 13, 14 can be round, triangular, and quadrilateral. Regardless of these shapes, the same effect can be obtained.

The base 11 also has two other opposite sides that are different from the sides at which the height registration parts 13, 14 are provided. The holding parts 15, 16 extend from the other two sides of the base 11 in horizontal (lateral) directions with the same width as the base 11 to press the electronic components 41, 42 toward the heat sink member 20. Specifically, the holding parts 15, 16 extend obliquely downward relative to the horizontal directions. The fixing parts 17, 18 are provided at the ends of the holding parts 15, 16, respectively. A tilt angle of the holding parts 15, 16 relative to the horizontal direction can be in a range of 0 to 90 degrees depending on the heights and materials of the electronic components 41, 42.

Because the fixing parts 17, 18 are firmly attached to the electronic components 41, 42, the electronic components 41, 42 contact the heat sink member 20 so as to fix the electronic components 41, 42 to the heat sink member 20 by surface contact. Thus, in the present embodiment, the fixing parts 17, 18 are bent in a horizontal direction in accordance with the shapes of the electronic components 41, 42 so as to securely and tightly contact the electronic components 41, 42. Therefore, a secure contact is obtained between the fixing parts 17, 18 and the electronic components 41, 42 by surface contact. However, when it is possible that the electronic components 41, 42 can securely and tightly contact the heat sink member 20 without providing the fixed parts 17, 18, the electronic components 41, 42 can be fixed to the heat sink member 20 by applying a pressing force toward the electronic components 41, 42 from tips of the holding parts 15, 16 without surface contact.

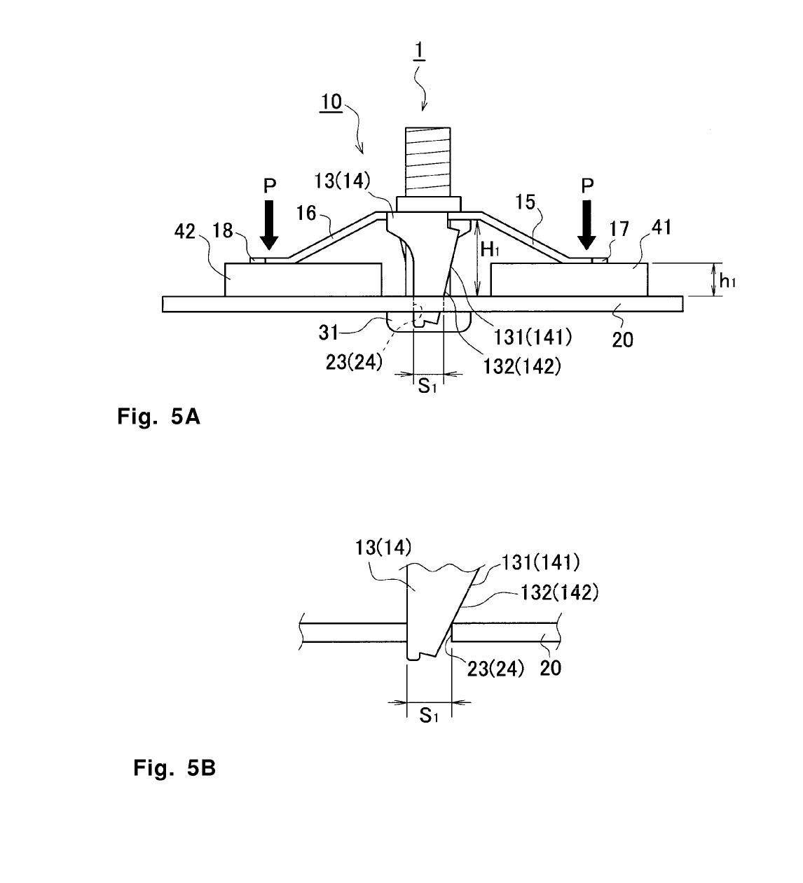

When the heat sink member 20 is tightened with the spring fixture 10 by the screw 30, the holding parts 15, 16 function as elastic members around the screw 30 that is tightened at the center of base 11. The fixed parts 17, 18 provided at the tips of the holding parts 15, 16 function to press the electronic components 41, 42 downward from above (the arrow P shown in FIG. 5A) so that the heat sink member 20 and the electronic components 41, 42 have tight surface contact and are fixed to each other.

### 2. Assembly Method of the Heat Sink Structure

Next, an assembly method of the heat sink structure 1 is explained. Specifically, procedures for fixing the electronic components 41, 42 by using the spring fixture 10 are explained with reference to FIGS. 1 through 3.

First, the electronic components 41, 42 are mounted on an upper surface of the heat sink member 20. An insulation sheet (not shown) may be provided between the heat sink member 20 and the electronic components 41, 42.

Next, the spring fixture 10 fits into the heat sink member 20 as shown in FIG. 3. The tip part of the height registration part 13 and the bent part 131 are inserted and fitted into the height adjustment hole 23. Similarly, the tip part of the height registration part 14 and the bent part 141 are inserted and fitted into the height adjustment hole 24. At this time, backlash does not occur because the height registration parts 13, (and the bent parts 131, 141) are tightly fitted with two sides of the height adjustment holes 23, 24.

At this time, the through screw hole 22 of the heat sink member 20 and the threaded hole 12 of the spring fixture 10 are aligned with each other in a vertical direction. Furthermore, the fixing part 17 is located to contact an upper surface of the electronic component 41, and the fixing part 18 is located to contact an upper surface of the electronic component 42.

As discussed above, a pressing force is dispersed because the height registration parts 13, 14 press and contact the heat sink member 20. Thus, an excessive pressing force is not applied to the electronic components 41, 42 from the fixing parts 17, 18.

Next, the screw 30 is inserted in the through screw hole 22 from below the heat sink member 20 (from an opposite side relative to the spring fixture 10). Then, the threaded part 32 of the screw 30 is tightened and fitted with the threaded hole 12 and the screw hole rising part 121. The strength of the tightening and fitting is adjusted by a screw driver. Adjustment of the strength is continued until the spring fixture 10, the heat sink member 20, the electronic components 41, 42, and the screw 30 will not come apart and backlash among the parts will not occur. The strength may be determined by the following predetermined standards as a default value, for example, the number of rotations of the screw driver, a protruding length of the treaded part 32 from the screw hole rising part 121, and a value of the pressing force P that is applied to the electronic components 41, 42. Then, the assembly processes for the heat sink structure 1 ends.

### 3. Adjustment of the Height Registration Part and Height Adjustment Hole

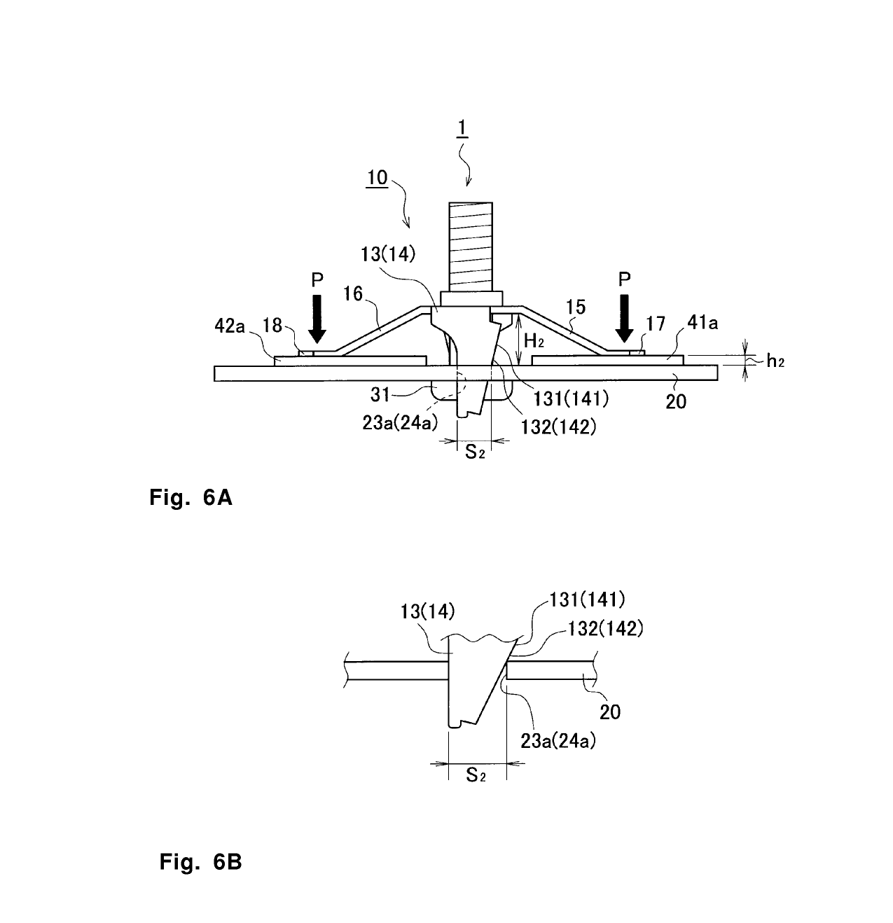

An assembly method for various electronic components will now be explained with reference to FIGS. 5A through 6B. The assembly method is for fixing electronic components 41a, 42a that have the different heights as compared to the electronic components 41, 42 to the heat sink member 20 by the spring fixture 10. FIG. 5A is a side view of the heat sink structure 1 according to the first embodiment of the present invention. FIG. 5B is a partial enlarged sectional view of the height adjustment hole 23(24) and the height registration part 13(14) of the heat sink structure 1 shown in FIG. 5A. FIG. 6A is a side view of the heat sink structure 1 when a size of a height adjustment hole 23a(24a) is larger than the height adjustment hole 23(24) of FIG. 5A. FIG. 6B is a partial enlarged sectional view of the height adjustment hole 23a(24a) and the height registration part 13(14) of the heat sink structure 1 shown in FIG. 6A.

As shown in FIGS. 5A and 5B, a height h1 corresponds to a height of the electronic components 41, 42. A height H1 corresponds to a distance between a lower surface of the base 11 and an upper surface of the heat sink member 20. A hole distance S1 corresponds to a distance between a point at which the sloped shape part 132(142) of the height registration part 13(14) contacts an internal surface of the height adjustment hole 23(24) and another point at which another side opposite to the sloped shape part 132(142) of the height registration part 13(14) contacts the internal surface of the height adjustment hole 23(24). The fixing parts 17, 18 contact upper surfaces of the electronic components 41, 42. Thus, the fixing parts 17, 18 press and fix the electronic components 41, 42 toward the heat sink member 20 and generate a pressing force P in a downward direction.

On the other hand, in FIGS. 6A and 6B, the electronic components 41a, 42a have a shorter height h2 that is lower than the height h1 of the electronic components 41, 42 shown in FIG. 5A. Because h1>h2, the fixing parts 17, 18 do not contact or do not properly contact the upper surface of the electronic components 41a, 42a if a distance between the lower surface of the base 11 and the upper surface of the heat sink member 20 is the same as the height H1 as shown in FIG. 5A. In this case, even though the threaded part 32 of the screw 30 is tightened and fitted with the threaded hole 12 and the screw hole rising part 121, the fixing parts 17, 18 cannot fix or cannot properly fix the electronic components 41a, 42a to the heat sink member 20 because the height H1 is too high for the thinner electronic components 41a, 42a.

The height registration parts 13, 14 are in the tapered shapes toward the tips of the height registration parts 13, 14. One side of the height registration parts 13, 14 is in the sloped shape so as to form the sloped shape parts 132, 142. Thus, a width of the body parts of the height registration parts 13, 14 close to the base 11 is wider than that of the tip parts of the height registration parts 13, 14. When the height registration parts 13, 14 are inserted into the height adjustment holes 23, 24, the height registration parts 13, 14 are fixed and held at a position at which the sloped shape parts 132, 142 contact the internal surface of the height adjustment holes 23, 24.

As shown in FIG. 6A, in order to fix the thinner electronic components 41a, 42a to the heat sink member 20, a hole distance S2 of the height adjustment holes 23a, 24a is longer than the hole distance S1 (S1<S2). In other words, the areas of the height adjustment holes 23a, 24a are larger than that of the height adjustment holes 23, 24. When the height registration parts 13, 14 (and the bent parts 131, 141) are inserted and fitted into the height adjustment holes 23a, 24a, a fitting and contacting position at which the height registration parts 13, 14 contact the internal surface of the height adjustment holes 23a, 24a is deeper as compared with the states shown in FIGS. 5A and 5B. Thus, the height registration parts 13, 14 are fixed and held at a position close to the base 11 as shown in FIGS. 6A and 6B. Therefore, a height H2 that corresponds to a distance between the lower surface of the base 11 and the upper surface of the heat sink member 20 can be lower than the height H1. As a result, the thinner electronic components 41a, 42a are securely fixed between the spring fixture 10, specifically the fixing parts 17, 18, and the heat sink member 20. In contrast, when the area of the height adjustment holes 23a, 24a is smaller than that of the height adjustment holes 23, 24 (S1>S2), the fitting and contacting position at which the height registration parts 13, 14 (and the bent parts 131, 141) contact the internal surface of the height adjustment holes 23a, 24a is shallower as compared with the states shown in FIGS. 5A and 5B. Thus, the height registration parts 13, 14 are fixed and held at a position close to the tip parts of the height registration parts 13, 14. Therefore, the height H2 can be higher than the height H1 in the above alternate case (S1>S2).

As discussed above, the fitting and contacting position at which the sloped shape parts 132, 142 of the height registration parts 13, 14 contact the internal surface of the height adjustment holes 23, 24 can be varied by changing the areas of the height adjustment holes 23, 24. Thus, a fixing position of the spring fixture 10 can be changed. The height adjustment for a distance between the lower surface of the base 11 and the upper surface of the heat sink member 20 can be performed. As a result, even though the height (thickness) of the electronic components 41, 42 is changed, the electronic components 41, 42 are securely fixed between the spring fixture 10 and the heat sink member 20 by changing the fitting and contacting position at which the sloped shape parts 132, 142 of the height registration parts 13, 14 contact the internal surface of the height adjustment holes 23, 24 in accordance with the areas of the height adjustment holes 23, 24.

### 4. Other Embodiments

As a second embodiment, more than two of the height registration parts and more than two of the height adjustment holes can be provided. For example, when three height registration parts and three height adjustment holes are provided, there are three contacting support areas between the spring fixture 10 and the heat sink member 20 so that more stable and reliable configurations can be realized.

Further, as a third embodiment, the electronic components 41, 42 are fixed to the heat sink member 20 by the tips of the holding parts 15, 16 without providing the fixing parts 17, 18. This configuration can lighten the burden for manufacturing the fixing parts 17, 18 and for providing materials for the fixing parts 17, 18.

As discussed above, according to the present application, the spring fixture can be used for electronic components having different heights by changing a size of the height adjustment hole provided in the heat sink member. As a result, several electronic components having different heights can be fixed to the heat sink member. Therefore, it is not necessary to change the designs and manufacturing methods for the spring fixture. Because one type of spring fixture with the same design and size can be used for several electronic components, it is not necessary to manufacture several variations of spring fixtures. Thus, it is possible to prevent the number of parts in inventory from increasing. The costs related to the spring fixture can also be decreased.

Further, since the height registration part provided at the spring fixture is embedded and fitted in the height adjustment hole provided in the heat sink member, the electronic components can be fixed and sandwiched by the spring fixture and the heat sink member. Thus, the positioning of the electronic components can be easily performed.

Because the height registration part comes into contact with the heat sink member, an excessive pressing force is not applied to the electronic components. Thus, breaking and cracking of the electronic components can be prevented.

The assembly process after the positioning of the electronic components is only the tightening of a screw. Thus, the assembly processes and process of operation can be simplified and efficiency can be increased.

Because the structure of the spring fixture is simple, it is not necessary to make the spring fixture with complex manufacturing processes. Thus, the manufacturing processes can also be simplified so that excellent mass productivity can be realized.

The spring fixture and the heat sink structure being thus described, it will be apparent that the same may be varied in many ways. Such variations are not to be regarded as a departure from the spirit and scope of the invention, and all such modifications as would be apparent to one of ordinary skill in the art are intended to be included within the scope of the following claims.

What is claimed is:

1. A spring fixture, comprising:
a base having first through fourth sides;
a first holding part extending from the first side of the base in a first lateral direction for pressing a first electronic component toward a heat sink member;
a second holding part extending from the second side of the base opposite to the first side, the second holding part extending in a second lateral direction opposite to the first lateral direction for pressing a second electronic component toward the heat sink member; and
a first height registration part extending from the third side of the base in a downward direction relative to the first and second lateral directions and having a tapered shape, wherein
the first and second electronic components are fixable to the heat sink member by the first and second holding parts.

2. The spring fixture, according claim 1, further comprising:
a threaded hole provided in the base; and
a screw securing the base and the heat sink member, wherein
the screw is inserted from the heat sink member to the base through the threaded hole to tighten the heat sink member to the base.

3. The spring fixture, according to claim 1, wherein
the first height registration part includes a body part at a proximal end close to the base, and a tip part at a distal end far from the base, and
the body part has a sloped shape so that a width of the tip part is narrower than a width of the body part.

4. The spring fixture, according to claim 1, further comprising:
a first fixing part provided at a first end of the first holding part, the first fixing part having a first planar surface; and
a second fixing part provided at a second end of the second holding part, the second fixing part having a second planar surface, wherein
the first and second planar surfaces contact the first and second electronic components, respectively, so as to fix the first and second electronic components to the heat sink member by surface contact.

5. The spring fixture, according to claim 1, further comprising:
a second height registration part extending from the fourth side of the base opposite to the third side, the second height registration part extending in the downward direction and having a tapered shape;
a first height adjustment hole provided in the heat sink member at a first location corresponding to the first height registration part; and
a second height adjustment hole provided in the heat sink member at a second location corresponding to the second height registration part, wherein
the first and second height registration parts are inserted through the first and second height adjustment holes, respectively, so that the first and second electronic components are fixed to the heat sink member by the first and second holding parts.

6. The spring fixture, according to claim 5, wherein
the second height registration part includes a body part at a proximal end close to the base, and a tip part at a distal end far from the base, and
the body part has a sloped shape so that a width of the tip part is narrower than a width of the body part.

7. A heat sink structure, comprising:
first and second electronic components;
a heat sink member; and
a spring fixture, the spring fixture including:
a base having first through fourth sides;
a first holding part extending from the first side of the base in a first lateral direction and pressing the first electronic component toward the heat sink member;
a second holding part extending from the second side of the base opposite to the first side, the second holding part extending in a second lateral direction opposite to the first lateral direction and pressing the second electronic component toward the heat sink member; and
a first height registration part extending from the third side of the base in a downward direction relative to the first and second lateral directions and having a tapered shape; and
a first height adjustment hole provided in the heat sink member at a first location corresponding to the first height registration part, wherein
the first height registration part is inserted through the first height adjustment hole so that the first and second electronic components are fixed to the heat sink member by the first and second holding parts.

8. The heat sink structure, according to claim 7, wherein
a first distance between the base and the heat sink member is changed by varying a size of the first height adjustment hole.

9. The heat sink structure, according claim 7, further comprising:
a threaded hole provided in the base;
a through hole provided in the heat sink member; and
a screw securing the base and the heat sink member, wherein
the screw is inserted from the heat sink member to the base through the through hole and the threaded hole to tighten the heat sink member to the base.

10. The heat sink structure, according to claim 7, wherein
the first height registration part includes a body part at a proximal end close to the base, and a tip part at a distal end far from the base, and
the body part has a sloped shape so that a width of the tip part is narrower than a width of the body part.

11. The heat sink structure, according to claim 7, further comprising:
a first fixing part provided at a first end of the first holding part, the first fixing part having a first planar surface; and
a second fixing part provided at a second end of the second holding part, the second fixing part having a second planar surface, wherein
the first and second planar surfaces contact the first and second electronic components, respectively, so as to fix the first and second electronic components to the heat sink member by surface contact.

12. The heat sink structure, according to claim 7, further comprising:
a second height registration part extending from the fourth side of the base opposite to the third side, the second height registration part extending in the downward direction and having a tapered shape; and
a second height adjustment hole provided in the heat sink member at a second location corresponding to the second height registration part, wherein
the second height registration part is inserted through the second height adjustment hole so that the first and second electronic components are fixed to the heat sink member by the first and second holding parts.

13. The heat sink structure, according to claim 12, wherein
the second height registration part includes a body part at a proximal end close to the base, and a tip part at a distal end far from the base, and
the body part has a sloped shape so that a width of the tip part is narrower than a width of the body part.

14. The heat sink structure, according to claim 12, wherein
a first distance between the base and the heat sink member is changed by varying sizes of the first and second height adjustment holes.
